(19) United States
(12) Patent Application Publication
(10) Pub. No.: US 2013/0161733 A1
(43) Pub. Date: Jun. 27, 2013

(54) SEMICONDUCTOR DEVICE

(71) Applicant: Elpida Memory, Inc., Tokyo (JP)

(72) Inventor: Kiminori HAYANO, Tokyo (JP)

(73) Assignee: ELPIDA MEMORY, INC., Tokyo (JP)

(21) Appl. No.: 13/722,172

(22) Filed: Dec. 20, 2012

(30) Foreign Application Priority Data
Dec. 27, 2011 (JP) 2011-285482

(51) Int. Cl. H01L 27/06

(52) U.S. Cl. CPC H01L 27/0629
USPC 257/329

(57) ABSTRACT

Disclosed herein a semiconductor device, which comprises: a vertical MOS transistor that has an upper diffusion layer, and a first lower diffusion layer disposed at a lower position than the upper diffusion layer; and a first diode that has a first well isolated from the first lower diffusion layer, and a second lower diffusion layer disposed at a lower position than the upper diffusion layer and formed in the first well. A surge voltage is discharged across the second lower diffusion layer and the first well when the surge voltage is applied.

### TECHNICAL FIELD

This application is based upon and claims the benefit of the priority of Japanese patent application No. 2011-285482, filed on Dec. 27, 2011, the disclosure of which is incorporated herein in its entirety by reference thereto.

The present disclosure relates to a semiconductor device having a MOS (Metal Oxide Semiconductor) transistor.

### BACKGROUND

As a downsized and high-integrated semiconductor device is developed, a semiconductor device is proposed, which has a vertical MOS transistor capable of occupying a smaller area than a lateral MOS transistor (see Japanese Patent Kokai Publication No. 2009-65024 (Patent Literature 1), which corresponds to US2009/065856A1 and Japanese Patent Kokai Publication No. 2009-81389 (Patent Literature 2), which corresponds to US2009/085102A1).

The vertical MOS transistor has a silicon pillar, a gate electrode formed along a side wall of the silicon pillar so as to surround the silicon pillar, and a source and drain formed in an upper and lower areas of the silicon pillar. In the vertical MOS transistor, the side wall of the silicon pillar acts as a channel region. This vertical MOS transistor is referred to as an SGT (Surrounding Gate Transistor).

The semiconductor device usually has an electrostatic discharge (ESD) protection element to protect an internal circuit from a surge voltage caused by the ESD (see Japanese Patent Kokai Publication No. 2009-283690 (Patent Literature 3)). The ESD protection element is connected to an external terminal and acts so as to prevent the surge voltage from being applied from the external terminal to the internal circuit by a clamp action, for example.

### SUMMARY

The following analysis is given in view of the present disclosure.

The ESD protection element may be made up by using the MOS transistor like the ESD protection element disclosed in Patent Literature 3. When the MOS transistor in the semiconductor device is designed as the vertical type, it is necessary to design the MOS transistor used in the ESD protection element also as the vertical type. However, because the vertical MOS transistor is a transistor having a new structure, optimization for the semiconductor device is not enough on certain aspects, and thus an element to be protected can not be protected or the ESD protection element itself may be broken when the vertical MOS transistor is used for the ESD protection element.

In the ESD protection element using the MOS transistor, a breakdown characteristic of a pn junction between a semiconductor substrate and an impurity diffusion layer for a source/drain electrode is used for the clamp action. Therefore, it is important for the ESD protection to stabilize the breakdown characteristic. In the semiconductor device described below, as illustrated in FIG. 12, however, the stabilization of the breakdown characteristic can not be sometimes achieved because there arise variation and lowering in the breakdown voltage, which are caused by a method of manufacturing the vertical MOS transistor.

FIG. 11 illustrates a schematic projection of a semiconductor device to show a positional relation to each element in the vertical MOS transistor. FIG. 12 illustrates a schematic cross-sectional view of the semiconductor device along a XII-XII line illustrated in FIG. 11. FIG. 12 is the schematic cross-sectional view of the semiconductor device 900 using a tenth vertical MOS transistor Qn12 as the electrostatic protection element. In the semiconductor device 900, a lower diffusion region 905 is electrically connected to a ground potential wiring 921 through a first contact plug 914. An upper diffusion region 912 is electrically connected to a pad 920, which is used for bonding, through a semiconductor region 911 and second contact plug 915. A gate electrode 907 is electrically connected to the ground potential wiring 921 through a third contact plug 916.

One example of a manufacturing method of the semiconductor device 900 having the vertical MOS transistor illustrated in FIGS. 11 and 12 will be explained below. FIG. 13 (FIGS. 13A-13E) and FIG. 14 (FIGS. 14A-14E) illustrate schematic flowcharts to explain one example of the manufacturing method of the semiconductor device 900. FIGS. 13 and 14 illustrate schematic cross-sections along the XII-XII line in FIG. 11.

First, an STI (Shallow Trench Isolation) insulating film 902 of a silicon oxide film or the like is formed as an element isolation region in a semiconductor substrate 901 of a first conductivity type (a p type, for example, shown below in the same way), and its surface is planarized (FIG. 13A).

Next, a first silicon pillar 901a and second silicon pillar 901b are formed by etching the semiconductor substrate 901. Before the etching is performed, a first mask 903 and second mask 904 are formed on regions to form the first silicon pillar 901a and second silicon pillar 901b in the semiconductor substrate 901 (FIG. 13B). A silicon oxide film (SiO₂) may be used as the first mask 903, for example, and a silicon nitride film (Si₃N₄) may be used as the second mask 904, for example. The silicon pillar 901a becomes a main body (channel part) of the vertical MOS transistor. The silicon pillar 901b is used to dispose a contact plug (described below) to apply a potential to the gate electrode of the vertical MOS transistor.

Next, an impurity of a second conductivity type (a n type, for example, shown below in the same way), such as arsenic (As), is injected into a region other than the first silicon pillar 901a and second silicon pillar 901b by an ion injection method or the like to form the lower diffusion layer 905. The lower diffusion layer 905 acts as one electrode of the source and drain regions. Next, thermal oxidation treatment is applied to form an oxide film, which is a gate insulation layer 906, on side walls of the first silicon pillar 901a and second silicon pillar 901b (FIG. 13C).

Next, a gate electrode precursor layer 907A of polysilicon or the like including an impurity, such as phosphorus (P) or the like, is deposited on the whole surface (FIG. 13D).

Next, etchback of the gate electrode precursor layer 907A is performed so as to leave the gate electrode precursor layer 907A on the side walls of the first silicon pillar 901a and second silicon pillar 901b. The gate electrode 907 is formed along on the side walls of the first silicon pillar 901a and second silicon pillar 901b (FIG. 13E). The gate electrode 907 may be formed as one body with electrical continuity that covers the side walls of the first silicon pillar 901a and second silicon pillar 901b by adjusting a gap between the first silicon pillar 901a and the second silicon pillar 901b. Although the gate electrode precursor layer 907A also remains on the side walls of the STI insulating film 902, this residual has no influence on the transistor action. The gate electrode precursor layer 907A that remains on the side walls of the STI insulating film 902 may remain floating or be electrically connected to the ground potential.

Next, a first insulating interlayer 908 of a silicon oxide film or the like is formed, and a top surface of the first insulating interlayer 908 is planarized by a CMP (Chemical Mechanical Polishing) method or the like (FIG. 14A).

Next, a third mask 909 of a silicon oxide film or the like is formed on the first insulating interlayer 908. Next, a first opening 909a is formed in the third mask 909 above the first silicon pillar 901a. Next, the second mask 904 on the first silicon pillar 901a is removed using the first opening 909a by wet etching or the like. A second opening 908a is formed in the first insulating interlayer 908 (FIG. 14B). The second mask 904 on the second silicon pillar 901b is left unremoved by being masked with the third mask 909.

Next, a sidewall that becomes a fourth mask 910 is formed on an inner wall of the second opening 908a. The fourth mask 910 may be formed by etchback after forming a silicon nitride film, for example. Next, a top surface (a silicon surface) of the first silicon pillar 901a is exposed by etching the first mask 903 on the first silicon pillar 901a using the fourth mask 910 as a mask (FIG. 14C).

Next, the semiconductor layer 911 is formed by a selective epitaxial growing method so as to fill the second opening 908a. Next, an upper diffusion layer 912 is formed by injecting an impurity of the second conductivity type such as arsenic or the like into the upper part of the first silicon pillar 901a by an ion injection method or the like (FIG. 14D). The upper diffusion layer 912 acts as the other electrode of the source electrode and drain electrode, namely an opposite electrode to the lower diffusion layer 905.

Next, a second insulating interlayer 913 of a silicon oxide film or the like is formed on the first insulating interlayer 908, and its top surface is planarized by the CMP method or the like. The second insulating interlayer 913 may be formed after removing the third mask 909 by the etching or the like. Next, first to third contact plugs 914-916 are formed, which are electrically connected to the lower diffusion layer 905, upper diffusion layer 912 and gate electrode 907 (FIG. 14E). The third contact plug 916 is disposed on the side wall of the second silicon pillar 901b that is not opposed to the side wall of the first silicon pillar 901a and is electrically connected to the gate electrode 907. In the downsized vertical MOS transistor, it is difficult to dispose both of the second contact plug 915 and third contact plug 916 on the first silicon pillar 901a so as not to short-circuit one with the other. Therefore, it becomes possible to dispose the third contact plug 916 at a position where the third contact plug 916 is not short-circuited with the second silicon pillar 915 by keeping the gate electrode 907 away from the side wall of the first silicon pillar 901a, using the side wall of the second silicon pillar 901b.

The semiconductor device 900 having the tenth vertical MOS transistor Qn12 can be manufactured with the above process.

A problem caused by the manufacturing method of the semiconductor device 900 will be explained below.

In the manufacturing process illustrated in FIGS. 13 and 14, under an influence of the process from forming the gate electrode 907 on the side walls of the silicon pillars 901a, 901b (FIG. 13E) to forming the upper diffusion layer 912 (FIG. 14D), there is a possibility that insulation withstand voltage (dielectric strength) between the upper diffusion layer 912 and the gate electrode 907 decreases or that breakdown voltage varies.

In FIG. 14C, for example, there is a possibility that the dielectric strength decreases by causing damage to the gate insulation film 906 when the first mask 903 on the first silicon pillar 901a is etched. When the surge voltage (electrostatic stress) is applied to the pad 920 in the semiconductor device 900, the breakdown arises between the upper diffusion layer 912 and the semiconductor substrate 901. If the dielectric strength is lowered, the electrostatic protection element, that is, the vertical MOS transistor itself, is broken before the electrostatic stress applied from the outside of the semiconductor device 900 is sufficiently discharged.

In the step of FIG. 14D, the semiconductor layer 911 sometimes grows excessively in the selective epitaxial growth of the semiconductor layer 911. If the semiconductor layer 911 grows to excess so as to cover the gate electrode 907, as illustrated in FIG. 15, an interaction between the gate electrode 907 and the semiconductor layer 911 lowers the dielectric strength.

In the step of FIG. 13E, there is also a possibility that the etchback treatment of the gate electrode 907 varies the breakdown voltage. The position of the upper end of the gate electrode 907 is easy to vary because the position depends on the etchback treatment. On the other hand, the position of the upper diffusion layer 912 has no influence on the variation of the top position of the gate electrode 907 because the upper diffusion layer 912 is formed by injecting the impurity into the silicon pillar 901a from above. That is, the upper diffusion layer 912 is independently formed at the upper part of the silicon pillar irrespective of the top position of the gate electrode 907. Therefore, a relative distance between the bottom surface (lower end) of the upper diffusion layer 912 and the upper end of the gate electrode 907 is uneven, and the breakdown voltage varies. Especially, as illustrated in FIG. 16, if the upper end of the gate electrode 907 is too close to the semiconductor layer 911, the dielectric strength is lowered.

If the breakdown voltage varies, the stable action of the electrostatic protection element can not be expected. If the breakdown voltage is lowered, the electrostatic stress can not be sufficiently discharged, and therefore there arises the problem that the element to be protected can not be prevented from being broken and that the electrostatic protection element itself is broken.

Although the external terminal is connected to the upper diffusion layer in the semiconductor device illustrated in FIG. 12, there is a possibility that the electrostatic protection element is broken even if the external terminal is connected to the lower diffusion layer. The thickness of the gate insulation film is difficult to be controlled in a corner of the lower part of the silicon pillar, for example. This causes the lowering of the dielectric strength or the unevenness of the breakdown voltage, and there is a possibility that the electrostatic protection element itself is broken as described above.

If not the vertical MOS transistor but a diode having the upper diffusion layer is used as the electrostatic protection element, there arises a problem of a discharging performance of the electrostatic protection element. FIGS. 17 and 18 illustrate schematic cross-sectional views of semiconductor devices that use the diode having the upper diffusion layer as the electrostatic protection element. The semiconductor devices 700, 800 illustrated in FIGS. 17 and 18 have the tenth vertical MOS transistor Qn 12 illustrated in FIG. 12.

The semiconductor device 700 illustrated in FIG. 17 has a tenth diode D10 that acts as the electrostatic protection element as well as the tenth vertical MOS transistor Q12. The tenth diode D10 has a well 931 of the second conductivity type (an N well, for example), an upper diffusion layer 933 of the first conductivity type (a p-type diffusion layer, for example), and an upper diffusion layer 932 of the second conductivity type (an n-type diffusion layer, for example). The upper diffusion layer 933 of the first conductivity type is formed in an upper part of a fourth silicon pillar 901d, and the upper diffusion layer 932 of the second conductivity type is formed in an upper part of a third silicon pillar 901c. The upper diffusion layer 933 of the first conductivity type is electrically connected to a pad 920 through a semiconductor layer 934 and contact plug 941. The upper diffusion layer 932 of the second conductivity type is electrically connected to a power potential wiring 922 through the semiconductor layer 934 and contact plug 942. An electrostatic stress applied to the pad 920 is discharged to the power potential wiring 922 through the upper diffusion layer 933 of the first conductivity type, the well 931 of the second conductivity type and the upper diffusion layer 932 of the second conductivity type.

The semiconductor device 800 illustrated in FIG. 18 has an eleventh diode D11 that acts as the electrostatic protection element as well as the tenth vertical MOS transistor Q12. The eleventh diode D11 has a well 931 of the second conductivity type (an N well, for example), a lower diffusion layer 935 of the first conductivity type (a p-type diffusion layer, for example), and an upper diffusion layer 932 of the second conductivity type (an n-type diffusion layer, for example). The upper diffusion layer 932 of the second conductivity type is formed in an upper part of a third silicon pillar 901c. The lower diffusion layer 935 of the first conductivity type is electrically connected to a pad 920 through a contact plug 941. The upper diffusion layer 932 of the second conductivity type is electrically connected to a power potential wiring 922 through the semiconductor layer 934 and contact plug 942. An electrostatic stress applied to the pad 920 is discharged to the power potential wiring 922 through the lower diffusion layer 935 of the first conductivity type, the well 931 of the second conductivity type and the upper diffusion layer 932 of the second conductivity type.

When the upper diffusion layer 932, 933 formed in the silicon pillars 901c, 901d is used for a discharging path like the tenth diode D10 and eleventh diode D11, the path that passes through the semiconductor layer becomes longer by the height of the silicon pillars. That is, the discharging path has higher resistance, and the discharging performance is lowered because the electrostatic current passes through the semiconductor layer having the higher resistance than the contact plug over a longer distance. Accordingly, when the diode having the upper diffusion layer is used as the electrostatic protection element, there is a possibility that the electrostatic protection element having enough discharging performance can not be obtained.

According to a first aspect of the present disclosure, there is provided a semiconductor device comprising: a vertical MOS transistor that has an upper diffusion layer, and a first lower diffusion layer disposed at a lower position than the upper diffusion layer; and a first diode that has a first well isolated from the first lower diffusion layer, and a second lower diffusion layer disposed at a lower position than the upper diffusion layer and formed in the first well. A surge voltage is discharged across the second lower diffusion layer and the first well when the surge voltage is applied.

### BRIEF DESCRIPTION OF THE DRAWINGS

FIG. 1 is a schematic cross-sectional view of a semiconductor device according to a first exemplary embodiment of the present disclosure.

FIG. 2 is a circuit diagram showing one example of the semiconductor device illustrated in FIG. 1.

FIGS. 3A and 3B are a schematic flowchart to explain a method of manufacturing the semiconductor device according to the first exemplary embodiment of the present disclosure.

FIGS. 4A and 4B are a schematic flowchart to explain the method of manufacturing the semiconductor device according to the first exemplary embodiment of the present disclosure.

FIGS. 5A and 5B are a schematic flowchart to explain the method of manufacturing the semiconductor device according to the first exemplary embodiment of the present disclosure.

FIGS. 6A and 6B are a schematic flowchart to explain the method of manufacturing the semiconductor device according to the first exemplary embodiment of the present disclosure.

FIG. 7 is a schematic cross-sectional view of a semiconductor device according to a second exemplary embodiment of the present disclosure.

FIG. 8 is a circuit diagram showing one example of the semiconductor device illustrated in FIG. 7.

FIG. 9 is one example of a circuit diagram of a semiconductor device according to a third exemplary embodiment of the present disclosure.

FIG. 10 is one example of a circuit diagram of a semiconductor device according to a fourth exemplary embodiment of the present disclosure.

FIG. 11 is a schematic plan view of a vertical MOS transistor.

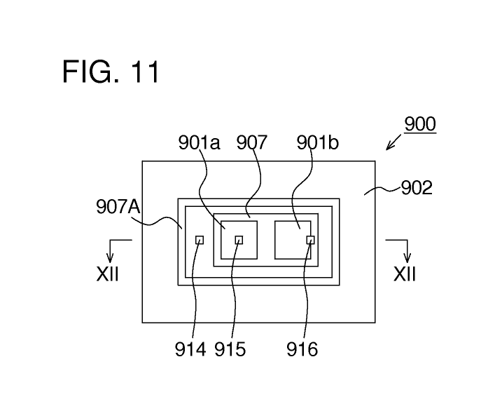

FIG. 12 is a schematic cross-sectional view of a vertical MOS transistor to explain a problem to be solved by the present disclosure.

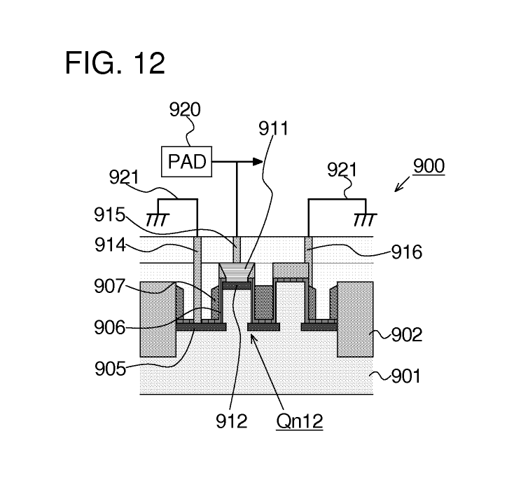

FIGS. 13A, 13B, 13C, 13D and 13E provide a schematic flow of steps to explain a method of manufacturing a vertical MOS transistor.

FIGS. 14A, 14B, 14C, 14D and 14E provide a schematic flow of steps to explain the method of manufacturing the vertical MOS transistor.

FIG. 15 is a schematic cross-sectional view of a semiconductor device to explain a problem to be solved by the present disclosure.

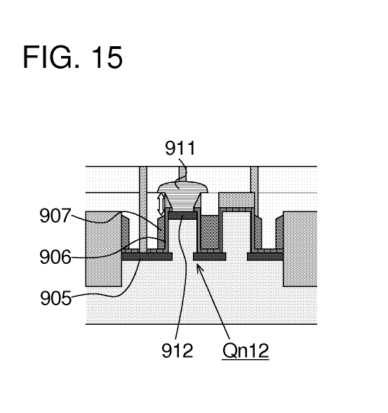

FIG. 16 is a schematic cross-sectional view of a semiconductor device to explain a problem to be solved by the present disclosure.

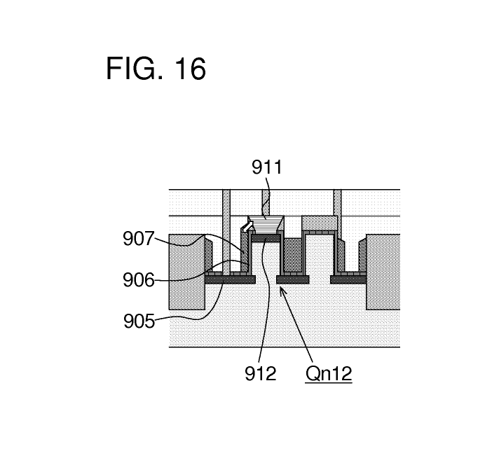

FIG. 17 is a schematic cross-sectional view of a semiconductor device to explain a problem to be solved by the present disclosure.

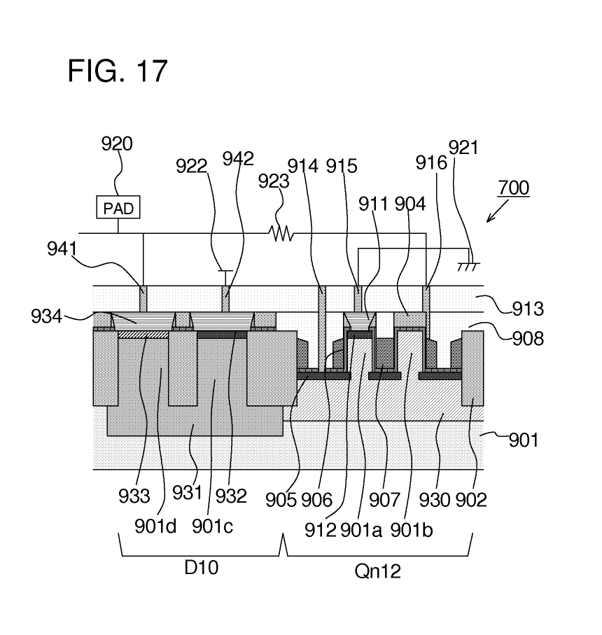

FIG. 18 is a schematic cross-sectional view of a semiconductor device to explain a problem to be solved by the present disclosure.

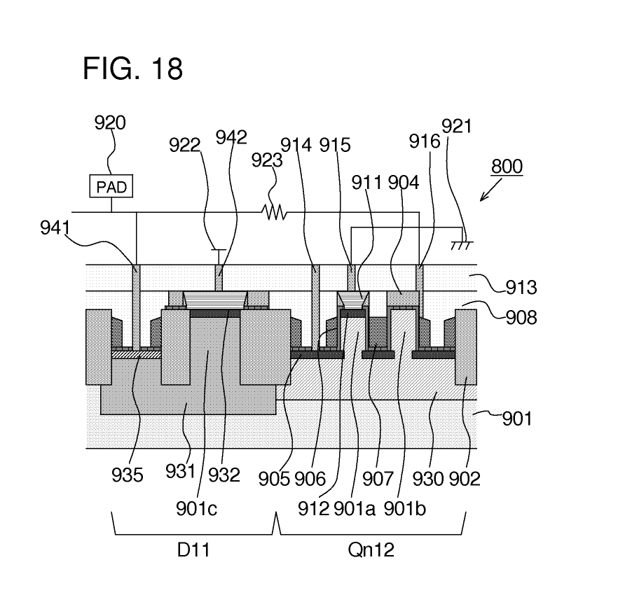

### PREFERRED EXAMPLES

Examples of exemplary embodiments of the present disclosure will be described hereafter with reference to drawings. Those skilled in the art will recognize that many alternative exemplary embodiments can be accomplished using the teachings of the present disclosure and that the disclosure is not limited to the exemplary embodiments illustrated for explanatory purposes.

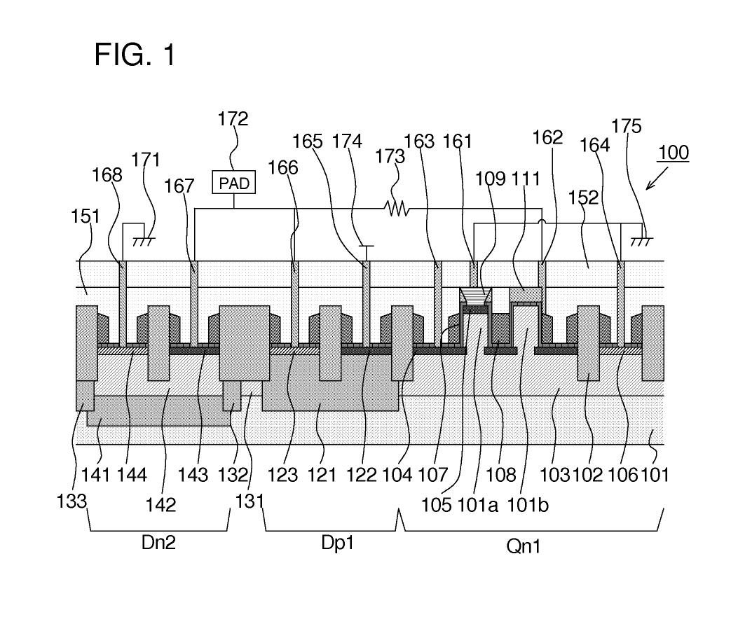

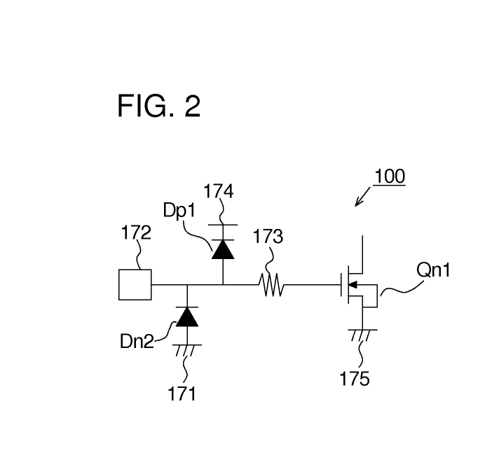

A semiconductor device according to a first exemplary embodiment of the present disclosure will be explained. FIG. 1 illustrates a schematic cross-sectional view of the semiconductor device according to the first exemplary embodiment of the present disclosure. FIG. 2 illustrates one example of a circuit diagram of the semiconductor device 100 illustrated in FIG. 1.

Ordinal numbers shown in the claims do not correspond to ordinal numbers shown in the following explanation. In the following exemplary embodiments and examples, reference signs are appended merely to make the understanding easy but not intended to limit the present disclosure to illustrated modes.

The semiconductor device 100 comprises a semiconductor substrate 101 of a first conductivity type (a p type in a mode illustrated in FIGS. 1 and 2), an element isolation region 102, a first vertical MOS transistor Qn1 of a second conductivity type (an n type in a mode illustrated in FIGS. 1 and 2) formed in the semiconductor substrate 101, a first diode Dp1 and second diode Dn2, a pad 172 that is electrically connected to the first vertical MOS transistor, first diode Dp1 and second diode Dn2, a first protection resistance 173 to decrease an electrostatic stress that is conducted from the pad 172 to the first vertical MOS transistor Qn1, a first ground potential wiring 175 that is electrically connected to the first vertical MOS transistor Qn1, a second ground potential wiring 171 that is electrically connected to the second diode Dn2, and a power potential wiring 174 that is electrically connected to the first diode Dp1. In this mode, the first diode Dp1 and second diode Dn2 act as electrostatic protection elements, and the first vertical MOS transistor Qn1 is an element to be protected. The pad 172 is a conductor (bonding pad) for a wire bonding or the like to electrically connect an external terminal, which is provided for input/output of a signal into/from the semiconductor device 100, with an internal circuit element of the semiconductor device, for example. The pad may include a conductor that is disposed to be connected to the external terminal through a though-silicon via (TSV) without the wire bonding. The first ground potential wiring 175 and second ground potential wiring 171 may be the same wiring.

In a region in which the first vertical MOS transistor Qn1 is formed, the semiconductor device 100 comprises a first well 103 of the first conductivity type (a p well, for example), a first silicon pillar 101a, a second silicon pillar 101b, a first lower diffusion layer 104 of the second conductivity type (an n-type impurity diffusion layer) formed around a lower part of the first silicon pillar 101a, an upper diffusion layer 105 of the second conductivity type (an n-type impurity diffusion layer) formed in an upper part of the first silicon pillar 101a, a gate insulation film 107 formed at least along a side wall of the first silicon pillar 101a between the first lower diffusion layer 104 and the upper diffusion layer 105, a gate electrode 108 formed on an outside of the gate insulation film 107, a semiconductor layer 109 that is formed on the upper diffusion layer 105 and is electrically connected to the upper diffusion layer 105, a first contact plug 161 that is electrically connected to the semiconductor layer 109, a second contact plug 162 that is electrically connected to the gate electrode 108 in a side wall of the second silicon pillar 101b, and a third contact plug 163 that is electrically connected to the first lower diffusion layer 104. The upper diffusion layer 105 and first lower diffusion layer 104 act as a source electrode and drain electrode. In the mode illustrated in FIG. 1, the gate insulation film 107 is formed along the side walls of the first silicon pillar 101a and second silicon pillar 101b. The gate electrode 108 is formed around the first silicon pillar 101a and second silicon pillar 101b in one body. The second contact plug 162 is prevented from being short-circuited with the first contact plug 161 on the first silicon pillar 101a by being connected to a part away form the first silicon pillar 101a, a part of the gate electrode 108 that is not opposite to the side wall of the first silicon pillar 101a, for example. The gate electrode 108 is electrically connected to the first protection resistance 173 and pad 172 through the second contact plug 162. The upper diffusion layer 105 is electrically connected to the first ground potential wiring 175 through the semiconductor layer 109 and first contact plug 161.

It is preferred that the semiconductor device 100 further comprises a second lower diffusion layer 106 of the first conductivity type (a p-type impurity diffusion layer, for example) to fix a potential of the first well 103, and a fourth contact plug 164 that electrically connects the second lower diffusion layer 106 with the first ground potential wiring 175. The second lower diffusion layer 106 is formed as the p-type diffusion layer in the semiconductor substrate 101, for example, and is isolated by the element isolation region 102. Therefore, a substrate potential of the first vertical MOS transistor Qn1 may be fixed to the ground potential.

In a region in which the first diode Dp1 is formed, the semiconductor device 100 further comprises a second well 121 of the second conductivity type (an n well, for example), a third lower diffusion layer 122 of the second conductivity type (an n-type impurity diffusion layer, for example), a fourth lower diffusion layer 123 of the first conductivity type (a p-type impurity diffusion layer, for example), a fifth contact plug 165 that is electrically connected to the third lower diffusion layer 122, and a sixth contact plug 166 that is electrically connected to the fourth lower diffusion layer 123. The third lower diffusion layer 122 and the fourth lower diffusion layer 123 are isolated by the element isolation region 102, respectively. The third lower diffusion layer 122 is electrically connected to the power potential wiring 174 through the fifth contact plug 165. The fourth lower diffusion layer 123 is electrically connected to the pad 172 through the sixth contact plug 166.

In a region in which the second diode Dn2 is formed, the semiconductor device 100 further comprises a deep well 141 of the second conductivity type (an n deep well, for example), a third well 142 of the first conductivity type (a p well, for example) formed on the deep well, a fifth lower diffusion layer 143 of the second conductivity type (a n-type impurity diffusion layer, for example), a sixth lower diffusion layer 144 of the first conductivity type (a p-type impurity diffusion layer, for example), a seventh contact plug 167 that is electrically connected to the fifth lower diffusion layer 143, and an eighth contact plug 168 that is electrically connected to the sixth lower diffusion layer 144. The fifth lower diffusion layer 143 and the sixth lower diffusion layer 144 are isolated by the element isolation region 102, respectively. The fifth lower diffusion layer 143 is electrically connected to the pad 172 through the seventh contact plug 167. The sixth lower diffusion layer 144 is electrically connected to the second ground potential wiring 171 through the eighth contact plug 168.

The fourth well 132 and fifth well 133 of the second conductivity type (the n well, for example) are electrically connected to the deep well 141 and give the electric potential to the deep well 141. The impurity diffusion layer 131 of the first conductivity type (the p-type impurity diffusion layer) is a region to prevent forming of an inversion layer.

In the semiconductor device 100, when the electrostatic stress is applied from the outside of the device through the pad 172, if the electrostatic stress has a positive electric potential, a bias is applied between the fourth lower diffusion layer 123 and the second well 121 in a forward direction, and the electrostatic stress is discharged to the power potential wiring 174 through the first diode Dp1. On the other hand, if the electrostatic stress has a negative electric potential, a bias is applied between the fifth lower diffusion layer 143 and the third well 142 in a forward direction, and the electrostatic stress is discharged to the second ground potential wiring 171 through the second diode Dn2. The electrostatic stress is hard to flow to the first vertical MOS transistor Qn1, which is the element to be protected, by the first protection resistance 173. This can protect the first vertical MOS transistor Qn1 from the electrostatic stress.

According to the present disclosure, because the electrostatic protection element is not the vertical MOS transistor but the diode, the problem caused by the manufacturing method of the vertical MOS transistor can be avoided. That is, the problems of the destruction of the electrostatic protection element, lack of the stability of the protection performance or the like caused by the lowering of the dielectric strength and the variation of the breakdown voltage can be inhibited. The diodes, which act as the electrostatic protection element, discharge the electrostatic stress through the lower diffusion layer without using the upper diffusion layer. Therefore, because the distance passing through the semiconductor substrate in the discharging path becomes short, the increasing of the resistance can be inhibited and the lowering of the discharging performance can be prevented.

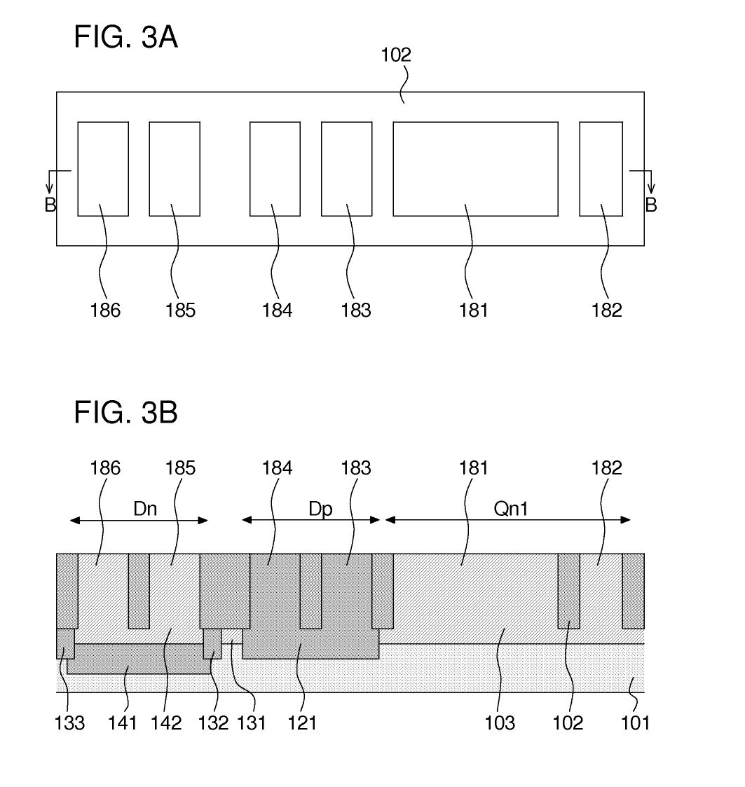

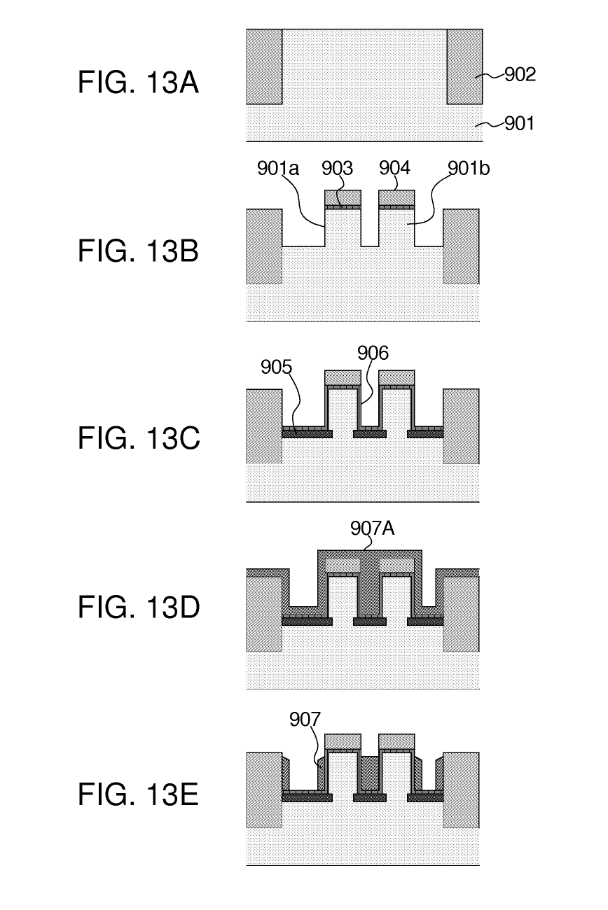

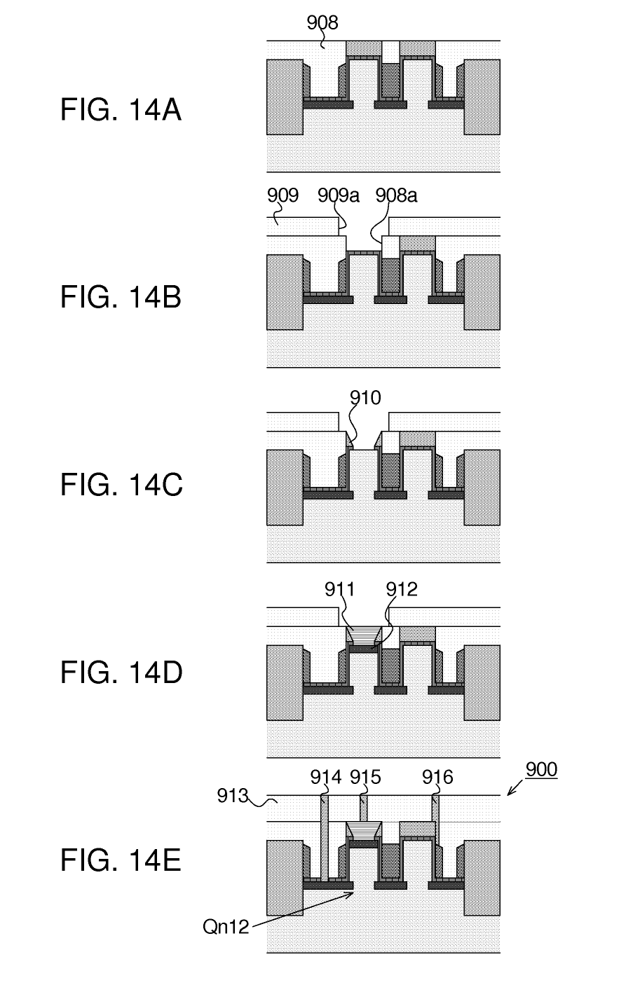

Next, a method of manufacturing the semiconductor device according to the first exemplary embodiment of the present disclosure will be explained. FIGS. 3-6 illustrate schematic flow charts to explain the method of the semiconductor device according to the first exemplary embodiment of the present disclosure. In FIGS. 3-6, FIGS. 3A-6A are schematic plan views, and FIGS. 3B-6B are schematic cross-sectional views along B-B lines of FIGS. 3A-6A. The manufacturing process of the vertical MOS transistor may be the same as the process illustrated in FIGS. 13-14.

First, an element isolation region 102 is formed in a semiconductor substrate 101 of a first conductivity type to form element forming regions 181-186. The first element isolation region 181 and second element isolation region 182 are formed in regions for forming a first vertical MOS transistor Qn1. The third element isolation region 183 and fourth element isolation region 184 are formed in regions for forming a first diode Dp1. The fifth element isolation region 185 and sixth element isolation region 186 are formed in regions for forming a second diode Dn2. Next, an impurity of a second conductivity type is injected into, mainly, the third element isolation region 183 and fourth element isolation region 184 to form a second well 121, fourth well 132 and fifth well 133. Next, an impurity of the first conductivity type is injected into, mainly, the first element forming region 181, second element forming region 182, fifth element forming region 185 and sixth element forming region 186 to form a first well 103, third well 142 and impurity diffusion layer 131. Next, in order to form a deep well 141, an impurity of the second conductivity type is injected into the fifth element forming region 185 and sixth element forming region 186 so as to cover a bottom of the third well 142. A side surface and bottom surface of the third well 142 of the first conductivity type are covered with the fourth well 132, fifth well 133 and deep well 141 of the second conductivity type, and the third well 142 is isolated from the semiconductor substrate 101 of the first conductivity type (FIGS. 3A and 3B).

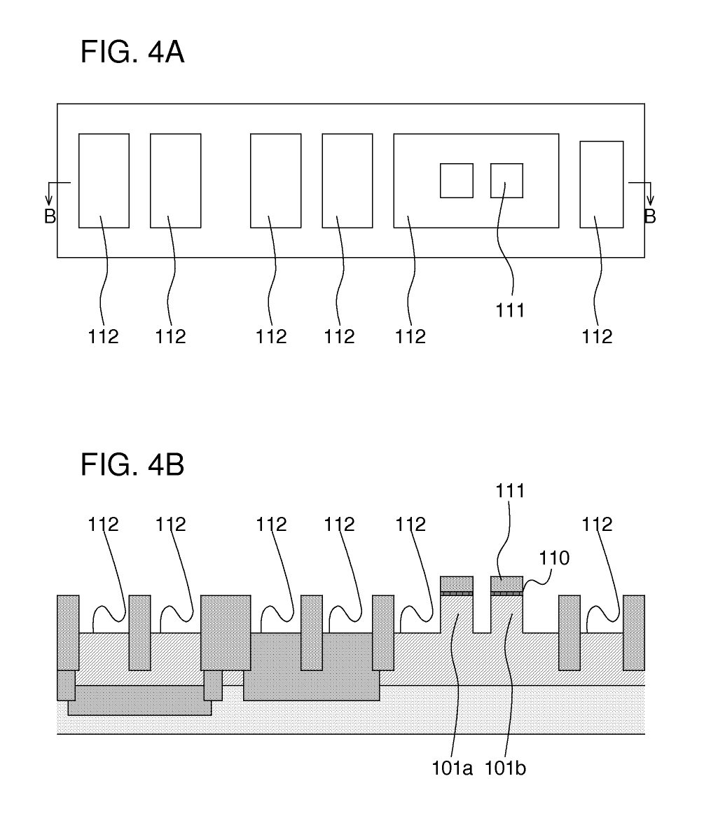

Next, in the first element forming region 181, a first mask 110 and a second mask 111 are layered on regions for forming a first silicon pillar 101a and second silicon pillar 101b. A silicon oxide film may be used as the first mask 110, for example. A silicon nitride film may be used as the second mask 111, for example. Next, the semiconductor substrate 101 is etched using the first mask 110 and second mask 111 as the masks to form dug portions 112 in which the semiconductor substrate 101 is dug to make it lower than the top surface of the element isolation region 102. The second to sixth element forming regions 182-186 are simultaneously etched in the same manner to form the dug portions 112, and the top surface of the semiconductor substrate 101 is lowered (FIGS. 4A and 4B). Therefore, upper diffusion layers are formed only in upper parts of the first silicon pillar 101a and second silicon pillar 101b.

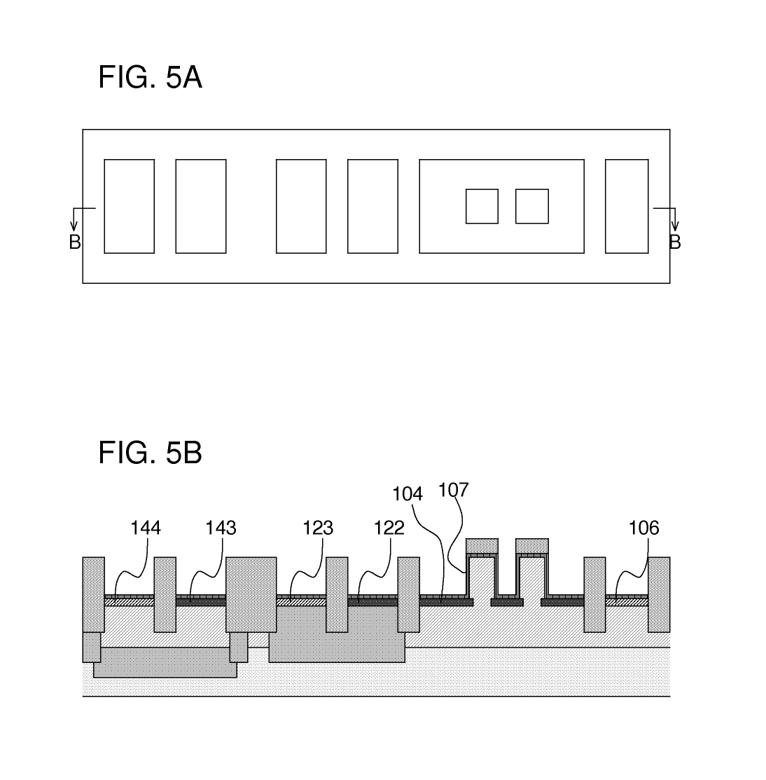

Next, a mask that exposes the first element forming region 181, third element forming region 183 and fifth element forming region 185 is formed. Next, an impurity is injected into the dug portions 112 of the first element forming region 181, third element forming region 183 and fifth element forming region 185 to form a first lower diffusion layer 104, third lower diffusion layer 122 and fifth lower diffusion layer 143 of the second conductivity type. Next, after the mask is removed, a mask that exposes the second element forming region 182, fourth element forming region 184 and sixth element forming region 186 is formed. Next, an impurity is injected into the dug portions 112 of the second element forming region 182, fourth element forming region 184 and sixth element forming region 186 to form a second lower diffusion layer 106, fourth lower diffusion layer 123 and sixth lower diffusion layer 144 of the first conductivity type. Next, after the mask is removed, oxide films are formed on the exposed surface of the semiconductor substrate 101 by thermal oxidation to form a gate insulation film 107 (FIGS. 5A and 5B).

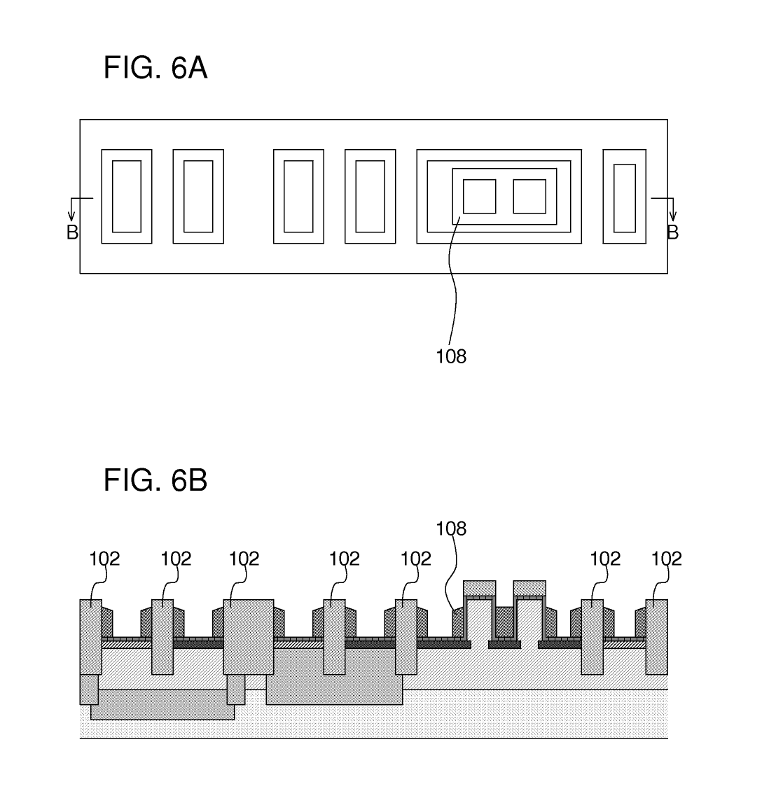

Next, a gate electrode 108 that has a shape of a sidewall is formed along side walls of the first silicon pillar 101a and second silicon pillar 101b by deposition and etchback of polysilicon. The sidewalls also remain on side walls of the insulation film formed for the element isolation in the element isolation region 102 (FIGS. 6A and 6B). Even if the height of the top surface of the gate electrode 108 is unstable, there is no influence on the dielectric resistance and protection performance of the first diode Dp1 and second diode Dn2. Metal such as titanium nitride, titanium, tungsten nitride, tungsten and the like may be used for the material of the gate electrode 108.

Next, a first insulating interlayer 151 is formed and then is planarized by the CMP method. Next, the second mask 111 and first mask 110 on the first silicon pillar 101a are removed to expose the upper part of the first silicon pillar 101a. Next, an impurity is injected into the upper part of the first silicon pillar 101a to form an upper diffusion layer 105. Next, a semiconductor layer 109 is formed on the upper diffusion layer 105. Next, a second insulating interlayer 152 is formed. Next, first to eighth contact plugs 161-168 are formed. Consequently, the semiconductor device 100 can be manufactured.

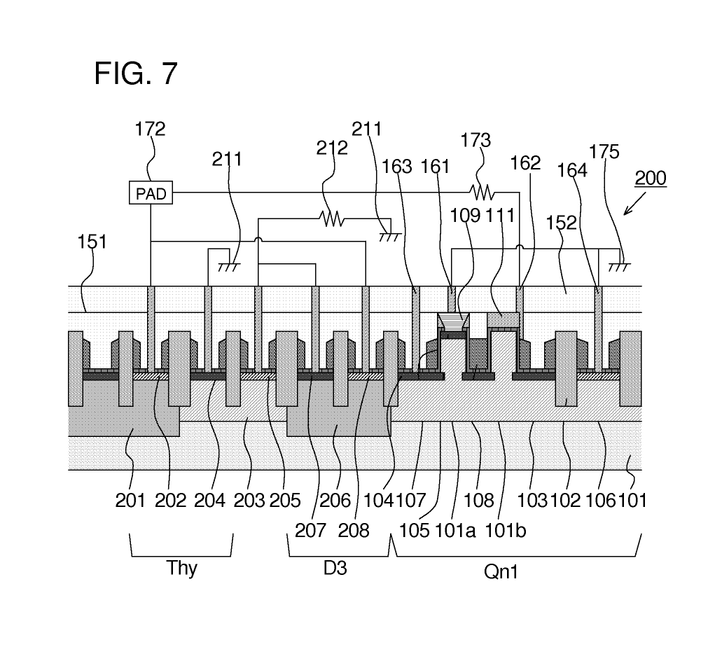

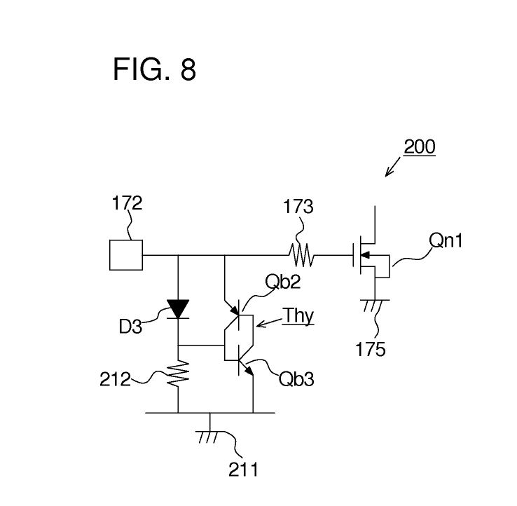

Next, a semiconductor device according to a second exemplary embodiment of the present disclosure will be explained. FIG. 7 illustrates a schematic cross-sectional view of the semiconductor device according to the second exemplary embodiment of the present disclosure. FIG. 8 illustrates one example of a circuit diagram of the semiconductor device 200 illustrated in FIG. 7. In FIGS. 7 and 8, the same reference signs are appended to the same elements as those of the first exemplary embodiment illustrated in FIGS. 1-6. The semiconductor device 200 according to the second exemplary embodiment uses a thyristor made up of two bipolar elements as the electrostatic protection element.

The semiconductor device 200 comprises a first vertical MOS transistor Qn1 same as the first exemplary embodiment, a thyristor Thy as the electrostatic protection element, and a third diode D3 to lower an action starting voltage. The thyristor Thy have a first bipolar element Qb2 (a PNP bipolar element, for example) and a second bipolar element Qb3 (an NPN bipolar element, for example), and the first bipolar element Qb2 and second bipolar element Qb3 form a PNPN structure. The third diode D3 lowers the starting potential of the electrostatic protection element by infusing a current into a base node of the second bipolar element Qb3 and raising the potential of the base node.

In the region in which the thyristor Thy is formed, the semiconductor device 200 comprises a sixth well 201 of a second conductivity type (an n well, for example), a seventh lower diffusion layer 202 of a first conductivity type (a p-type impurity diffusion layer, for example) formed in the sixth well, a seventh well 203 of the first conductivity type (a p well, for example) formed close to the sixth well, an eighth lower diffusion layer 204 of the second conductivity type (an n-type impurity diffusion layer) and ninth lower diffusion layer 205 of the first conductivity type (a p-type impurity diffusion layer) 205 that are formed n the seventh well 203. The seventh lower diffusion layer 202 is electrically connected to the pad 172 through a contact plug. The eighth lower diffusion layer 204 is electrically connected to a third ground potential wiring 211 through a contact plug. The ninth lower diffusion layer 205 is electrically connected to a first resistance 212 to lower the action starting potential and a third ground potential wiring 211 through a contact plug.

The first bipolar element Qb2 is made up of the seventh lower diffusion layer 202, sixth well 201 and seventh well 203, for example. The second bipolar element Qb3 is made up of the sixth well 201, seventh well 203 and eighth lower diffusion layer 204, for example.

In the region in which the third diode D3 is formed, the semiconductor device 200 comprises an eighth well 206 of the second conductivity type (an n well, for example), a tenth lower diffusion layer 207 of the second conductivity type (an n-type impurity diffusion layer, for example) and eleventh lower diffusion layer 208 of the first conductivity type (an p-type impurity diffusion layer) 208 that are formed in the eighth well 206. The eleventh lower diffusion layer 208 is electrically connected to the pad 172 through a contact plug. The tenth lower diffusion layer 207 is electrically connected to the first resistance 212 and the third ground potential wiring 211. In the mode illustrated in FIGS. 7 and 8, the third diode D3 is one diode element, but the third diode D3 may be a plurality of diode elements connected in series. It is preferred that the number of the diode element is determined according to an effect of lowering the starting potential of the electrostatic protection element and a magnitude of leak current in an ordinary action.

When the electrostatic stress is applied to the pad 172, the electrostatic stress is discharged to the third ground potential wiring 211 by the thyristor Thy and third diode D3, and the element to be protected (the first vertical MOS transistor Qn1, for example) is protected.

In the second exemplary embodiment, because the thyristor Thy and third diode D3 are used as the electrostatic protection element, there is no problem of the lowering of the dielectric strength, the variation of the breakdown voltage and the like in a manner that the vertical MOS transistor is used as the electrostatic protection element. The seventh to eleventh lower diffusion layers 202, 204, 205, 207, 208 are formed at the same level as the first lower diffusion layer 104 of the first vertical MOS transistor Qn1. Therefore, the distance that the electrostatic stress passes through the semiconductor substrate 101 can be shortened by using no upper diffusion layer in the electrostatic protection element, and the lowering of the discharging performance can be inhibited.

The semiconductor device 200 according to the second exemplary embodiment may be manufactured by basically using the same method as that explained in the first exemplary embodiment.

In the first and second exemplary embodiments, although the n-channel type MOS transistor is shown as the vertical MOS transistor, a p-channel type MOS transistor may be used.

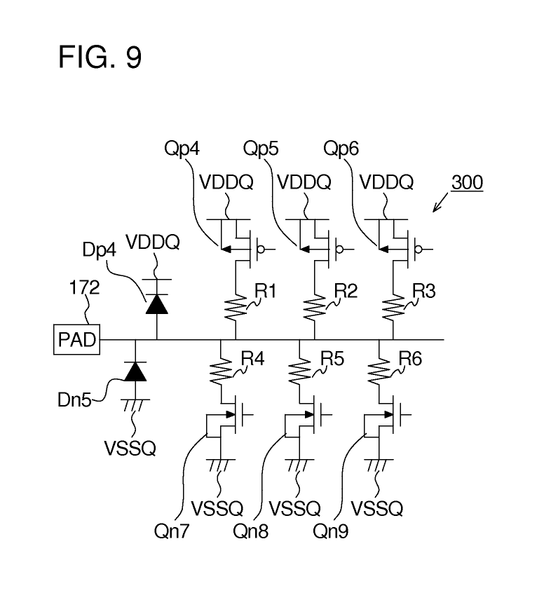

Next, a semiconductor device according to a third exemplary embodiment of the present disclosure will be explained. FIG. 9 illustrates one example of a circuit diagram of the semiconductor device according to the third exemplary embodiment of the present disclosure.

The semiconductor device 300 comprises a pad 172, second to fourth vertical MOS transistors Qp4-Qp6 of a p-channel type that are electrically connected to the pad 172 and are elements to be protected, fifth to seventh vertical MOS transistors Qn7-Qn9 of an n-channel type that are electrically connected to the pad 172 and are elements to be protected, second to seventh protection resistances R1-R6 that are provided between the pad 172 and the second to seventh vertical MOS transistors Qp4-Qp6, Qn7-Qn9, respectively, and act as the protection resistances for the second to seventh vertical MOS transistors Qp4-Qp6, Qn7-Qn9, and a fourth diode Dp4 and fifth diode Dn5 that are electrically connected to the pad 172 and act as electrostatic protection elements. The second to seventh vertical MOS transistors Qp4-Qp6, Qn7-Qn9 may be output transistors, for example, and may be used for a fine adjustment of a characteristic of a wave form. The second to fourth vertical MOS transistors Qp4-Qp6 are electrically connected to a power potential wiring VDDQ for the output transistors and the fifth to seventh vertical MOS transistors Qn7-Qn9 are electrically connected to a ground potential wiring VSSQ for the output transistors. The fourth diode Dp4 is electrically connected to the power potential wiring VDDQ, and the fifth diode is electrically connected to the ground potential wiring VSSQ.

All impurity diffusion regions in the fourth diode Dp4 and fifth diode Dn5 are not formed at the same level as the upper diffusion layer in the second to seventh vertical MOS transistors Qp4-Qp6, Qn7-Qn9 but formed at the same level as the lower diffusion layer.

The fourth diode Dp4, fifth diode Dn5 and second to seventh protection resistances R1-R6 act as the electrostatic protection elements for the electrostatic stress applied to the pad 172 by the same action as the first diode, second diode and protection resistance in the first exemplary embodiment and protect the second to seventh vertical MOS transistors Qp4-Qp6, Qn7-Qn9 from the electrostatic stress.

The second to seventh vertical MOS transistors Qp4-Qp6, Qn7-Qn9 may have the same structure as the vertical MOS transistor illustrated in FIG. 1. The semiconductor device 300 according to the third exemplary embodiment may be manufactured by basically using the same method as that explained in the first exemplary embodiment.

In the third exemplary embodiment, the lowering of the dielectric resistance, the instability of the protection performance and the lowering of the discharging performance can be prevented.

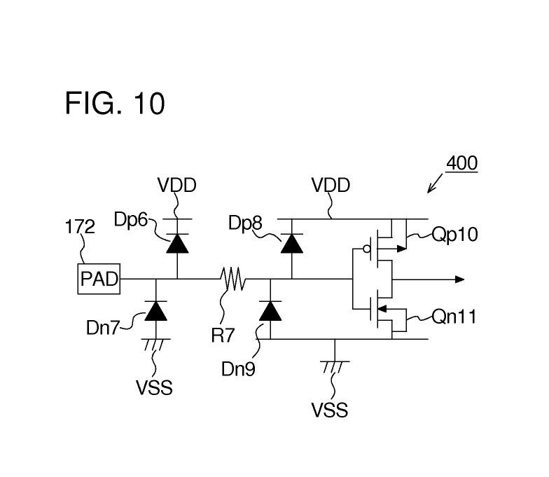

Next, a semiconductor device according to a fourth exemplary embodiment of the present disclosure will be explained. FIG. 10 illustrates one example of a circuit diagram of the semiconductor device according to the fourth exemplary embodiment of the present disclosure. The first to third exemplary embodiments deal with the electrostatic stress caused by a contact of a charged body with a pad from the outside, that is, a HBM (Human Body Model) and MM (Machine Model), whereas the semiconductor device 400 according to the fourth exemplary embodiment relates to a CDM (Charged Device Model) that deals with an electric discharge caused by a charged device.

The semiconductor device 400 comprises a pad 172, an eighth vertical MOS transistor Qp10 of a p-channel type and ninth vertical MOS transistor Qn11 of an n-channel type that are electrically connected to the pad 172 and are elements to be protected, an eighth protection resistance R7 that are provided between the pad 172 and the eighth and ninth vertical MOS transistors Qp10, Qn11, respectively, and act as the protection resistances for the eighth and ninth vertical MOS transistors Qp10, Qn11, a sixth diode Dp6 and seventh diode Dn7 that are connected between the pad 172 and the eighth protection resistance R7 and act as electrostatic protection elements, and an eighth diode Dp8 and ninth diode Dn9 that are connected between the eighth protection resistance R7 and the eighth and ninth vertical MOS transistors Qp10, Qn11 and act as electrostatic protection elements. The eighth and ninth vertical MOS transistors Qp10, Qn11 form an inverter circuit. The eighth vertical MOS transistor Qp10 is electrically connected to a power potential wiring VDD. The ninth vertical MOS transistor Qn11 is electrically connected to a ground potential wiring VSS. The sixth diode Dp6 and eighth diode Dp8 are electrically connected between the pad 172 and the power potential wiring VDD. The seventh diode Dn7 and ninth diode Dn9 are electrically connected between the pad 172 and the ground potential wiring VSS.

All impurity diffusion regions in the sixth diode Dp6, seventh diode Dn7, eighth diode Dp8 and ninth diode Dn9 are not formed at the same level as the upper diffusion layer in the eighth and ninth vertical MOS transistors Qp10, Qn11 but formed at the same level as the lower diffusion layer.

The sixth diode Dp6, seventh diode Dn7 and eighth protection resistance R7 act in the same action as the first diode, second diode and first protection resistance in the first exemplary embodiment and protect the eighth and ninth vertical MOS transistors Qp10, Qn11 from the electrostatic stress that comes from the pad 172. On the other hand, the eighth diode Dp8 and ninth diode Dn9 protect the eighth and ninth vertical MOS transistors Qp10, Qn11 from the electrostatic stress when the electrification of the device itself is discharge from the pad 172. That is, when the potential difference arises between a gate electrode and a source electrode (substrate) in the eighth vertical MOS transistor Qp10, the electrostatic stress is discharged from the eighth diode Dp8 to the power potential wiring VDD. When the potential difference arises between a gate electrode and a source electrode (substrate) in the ninth vertical MOS transistor Qn11, the electrostatic stress is discharged from the ninth diode Dn9 to the ground potential wiring VSS.

The eighth and ninth vertical MOS transistors Qp10, Qn11 may have the same structure as the vertical MOS transistor illustrated in FIG. 1. The semiconductor device 400 according to the fourth exemplary embodiment may be manufactured by basically using the same method as that explained in the first exemplary embodiment.

In the fourth exemplary embodiment, the lowering of the dielectric resistance, the instability of the protection performance and the lowering of the discharging performance can be prevented.

According to a preferred mode of the first aspect, the first lower diffusion layer and the second lower diffusion layer have top surfaces having almost same depth relative to the upper diffusion layer.

According to a preferred mode of the first aspect, the first diode further has a third lower diffusion layer disposed at a lower position than the upper diffusion layer and formed in the first well. The first well and the third lower diffusion layer have a first conductivity type. The second lower diffusion layer has a second conductivity type. The first diode includes the first well and the second lower diffusion layer.

According to a preferred mode of the first aspect, the third lower diffusion layer has a top surface having almost same depth as a top surface of the second lower diffusion layer relative to the upper diffusion layer.

According to a preferred mode of the first aspect, the second lower diffusion layer is electrically connected to an external terminal. The third lower diffusion layer is electrically connected to a ground potential wiring. The surge voltage is discharged to the ground potential wiring through the first diode and the third lower diffusion layer.

According to a preferred mode of the first aspect, the semiconductor device further comprises a second diode that has a second well isolated from the first lower diffusion layer and the first well, and a fourth lower diffusion layer disposed at a lower position than the upper diffusion layer and formed in the second well. The surge voltage is discharged between (across) the fourth lower diffusion layer and the second well when the surge voltage is applied.

According to a preferred mode of the first aspect, the first lower diffusion layer and the fourth lower diffusion layer have the top surfaces having almost same depth relative to the upper diffusion layer.

According to a preferred mode of the first aspect, the second diode further has a fifth lower diffusion layer disposed at a lower position than the upper diffusion layer and formed in the second well. The fourth lower diffusion layer has a first conductivity type. The second well and the fifth lower diffusion layer have a second conductivity type. The second diode is made up of the second well and the fourth lower diffusion layer.

According to a preferred mode of the first aspect, the fifth lower diffusion layer has a top surface having almost same depth as a top surface of the fourth lower diffusion layer to the upper diffusion layer.

According to a preferred mode of the first aspect, the fourth lower diffusion layer is electrically connected to an external terminal; the fifth lower diffusion layer is electrically connected to a power potential wiring. The surge voltage is discharged to the power potential wiring through the second diode and the fifth lower diffusion layer.

According to a preferred mode of the first aspect, the semiconductor device further comprises: a thyristor that has the first well, the second lower diffusion layer, a third well that is electrically connected to the first well, and a sixth lower diffusion layer disposed at a lower position than the upper diffusion layer and formed in the third well.

According to a preferred mode of the first aspect, the second lower diffusion layer and the sixth lower diffusion layer have the top surfaces having almost same depth relative to the upper diffusion layer.

According to a preferred mode of the first aspect, the second lower diffusion layer and the third well have a first conductivity type. The sixth lower diffusion layer and the first well have a second conductivity type. The second lower diffusion layer is electrically connected to an external terminal. The sixth lower diffusion layer is electrically connected to a ground potential wiring. The surge voltage is discharged to the ground potential wiring through the thyristor.

According to a preferred mode of the first aspect, the semiconductor device further comprises a fourth well of the second conductivity type that is electrically connected to the third well; and a seventh lower diffusion layer of the first conductivity type that is disposed at a lower position than the upper diffusion layer and formed in the fourth well. The seventh lower diffusion layer is electrically connected to the external terminal.

According to a preferred mode of the first aspect, the second lower diffusion layer and the seventh lower diffusion layer have the top surfaces having almost same depth relative to the upper diffusion layer.

According to a preferred mode of the first aspect, the semiconductor device further comprises a protection resistance that is provided between the vertical MOS transistor and an external terminal and that decreases the surge voltage to the vertical MOS transistor. The vertical MOS transistor is an element to be protected that is protected by the first diode and the protection resistance.

According to a preferred mode of the first aspect, the semiconductor device further comprises a protection resistance that is provided between the vertical MOS transistor and an external terminal and that decreases the surge voltage to the vertical MOS transistor. The semiconductor device has a plurality of diodes that are at least any one of the first diodes and the second diodes. Among the plurality of the diodes, one diode is connected to a ground potential wiring or power potential wiring between an external terminal and the protection resistance, and other diode is connected to a ground potential wiring or power potential wiring between the protection resistance and the vertical MOS transistor. The vertical MOS transistor is an element to be protected that is protected by the plurality of the diodes and the protection resistance.

According to a second aspect of the present disclosure, there is provided a semiconductor device comprising: an upper diffusion layer disposed in a semiconductor substrate surface; a first lower diffusion layer of a first conductivity type and a second lower diffusion layer of a second conductivity type that are disposed in a lower surface lower than the semiconductor substrate surface; an insulating film that isolates the first lower diffusion layer from the second lower diffusion layer and that upwardly projects from the lower surface; and a first well of the first conductivity type disposed in a lower position than the first lower diffusion layer, the second lower diffusion layer and the insulating film. A surge voltage is discharged between (across) the second lower diffusion layer and the first well when the surge voltage is applied.

According to a preferred mode of the second aspect, the semiconductor device further comprises a conductive sidewall formed on a side wall of the insulating film.

According to a preferred mode of the second aspect, the first lower diffusion layer is electrically connected to a ground potential wiring. The second lower diffusion layer is electrically connected to an external terminal. The surge voltage is discharged to the ground potential wiring through the second lower diffusion layer, the first well and the first lower diffusion layer.

According to a third aspect of the present disclosure, there is provided a method of manufacturing a semiconductor device, comprising: forming a first well and a second well, which are divided by an element isolation region, in a semiconductor substrate; etching the first well and the second well so as to make silicon pillars in the first well and to make etched regions of the first well and the second well lower than a top surface of the element isolation region; forming impurity diffusion layers by injecting impurities into the etched region of the first well, an upper part of the silicon pillar, and the etched region of the second well; forming a vertical MOS transistor having the impurity diffusion layers formed in the etched region of the first well and the upper part of the silicon pillar as a source electrode and drain electrode; and forming an electrostatic protection element for the vertical MOS transistor that has a first diode made up of the impurity diffusion layer of the second well and the second well.

According to a preferred mode of the third aspect, in the step of forming the first well and the second well, a third well that is divided by the element isolation region and has a different conductivity type from that of the second well is further formed in a semiconductor substrate. In the step of etching the first well and second well, an etched surface of the third well is also made lower than the top surface of the element isolation region. In the step of forming the impurity diffusion layer, an impurity diffusion layer having a different conductivity type from that of the impurity diffusion layer of the second well is formed in the third well. In the step of forming the electrostatic protection element for the vertical MOS transistor, a second diode is formed, which is made up of the impurity diffusion layer of the third well and the third well.

According to a preferred mode of the third aspect, in the step of forming the vertical MOS transistor, a conductive material is deposited on said first well. A gate electrode in the vertical MOS transistor is formed along a side wall of the silicon pillar by etchback of the conductive material.

The semiconductor device and manufacturing method thereof of the present disclosure are explained based on the above exemplary embodiments, but are not limited to the above exemplary embodiments, and may include any modification, change and improvement to the disclosed various elements (including each element of each claim, each element of each example, each element of each figure and others) within the scope of the present disclosure and based on the basic technical idea of the present disclosure. Within the scope of the claims of the present disclosure, various combinations, displacements and selections of disclosed elements (including each element of each claim, each element of each example, each element of each figure and others) are available. Any conductivity type of a vertical MOS transistor, any of an n-channel type and a p-channel type, may make up an electrostatic protection element by applying the present disclosure.

A further problem, object and exemplary embodiment of the present disclosure become clear from the entire disclosure of the present invention including claims and drawings.

Particularly, any numerical range disclosed herein should be interpreted that any intermediate values or subranges falling within the disclosed range are also concretely disclosed even without specific recital thereof.

What is claimed is:

1. A semiconductor device, comprising:
a vertical MOS transistor that has an upper diffusion layer, and a first lower diffusion layer disposed at a lower position than said upper diffusion layer; and
a first diode that has a first well isolated from said first lower diffusion layer, and a second lower diffusion layer disposed at a lower position than said upper diffusion layer and formed in said first well; wherein
a surge voltage is discharged across said second lower diffusion layer and said first well when the surge voltage is applied.

2. The semiconductor device according to claim 1, wherein
said first lower diffusion layer and said second lower diffusion layer have top surfaces disposed at an almost same depth relative to said upper diffusion layer.

3. The semiconductor device according to claim 1, wherein
said first diode further has a third lower diffusion layer disposed at a lower position than said upper diffusion layer and formed in said first well;
said first well and said third lower diffusion layer are of a first conductivity type;
said second lower diffusion layer is of a second conductivity type; and
said first diode includes said first well and said second lower diffusion layer.

4. The semiconductor device according to claim 3, wherein
said third lower diffusion layer has a top surface disposed at an almost same depth as a top surface of said second lower diffusion layer relative to said upper diffusion layer.

5. The semiconductor device according to claim 3, wherein
said second lower diffusion layer is electrically connected to an external terminal;
said third lower diffusion layer is electrically connected to a ground potential wiring; and
the surge voltage is discharged to the ground potential wiring through said first diode and said third lower diffusion layer.

6. The semiconductor device according to claim 1, further comprising:
a second diode that has a second well isolated from said first lower diffusion layer and said first well, and a fourth lower diffusion layer disposed at a lower position than said upper diffusion layer and formed in said second well; wherein
the surge voltage is discharged across said fourth lower diffusion layer and said second well when the surge voltage is applied.

7. The semiconductor device according to claim 6, wherein
said first lower diffusion layer and said fourth lower diffusion layer have the top surfaces disposed at an almost same depth relative to said upper diffusion layer.

8. The semiconductor device according to claim 6, wherein
said second diode further has a fifth lower diffusion layer disposed at a lower position than said upper diffusion layer and formed in said second well;
said fourth lower diffusion layer is of a first conductivity type;
said second well and said fifth lower diffusion layer are of a second conductivity type; and
said second diode is made up of said second well and said fourth lower diffusion layer.

9. The semiconductor device according to claim 8, wherein
said fifth lower diffusion layer has a top surface disposed at an almost same depth as a top surface of said fourth lower diffusion layer relative to said upper diffusion layer.

10. The semiconductor device according to claim 8, wherein
said fourth lower diffusion layer is electrically connected to an external terminal;
said fifth lower diffusion layer is electrically connected to a power potential wiring; and
the surge voltage is discharged to the power potential wiring through said second diode and said fifth lower diffusion layer.

11. The semiconductor device according to claim 1, further comprising:
a thyristor that has said first well, said second lower diffusion layer, a third well that is electrically connected to said first well, and a sixth lower diffusion layer disposed at a lower position than said upper diffusion layer and formed in said third well.

12. The semiconductor device according to claim 11, wherein
said second lower diffusion layer and said sixth lower diffusion layer have the top surfaces disposed at an almost same depth relative to said upper diffusion layer.

13. The semiconductor device according to claim 11, wherein
said second lower diffusion layer and said third well have a first conductivity type;
said sixth lower diffusion layer and said first well have a second conductivity type;
said second lower diffusion layer is electrically connected to an external terminal;
said sixth lower diffusion layer is electrically connected to a ground potential wiring; and
the surge voltage is discharged to the ground potential wiring through said thyristor.

14. The semiconductor device according to claim 13, further comprising:
a fourth well of the second conductivity type that is electrically connected to said third well; and
a seventh lower diffusion layer of the first conductivity type that is disposed at a lower position than said upper diffusion layer and formed in said fourth well; wherein
said seventh lower diffusion layer is electrically connected to said external terminal.

15. The semiconductor device according to claim 14, wherein
said second lower diffusion layer and said seventh lower diffusion layer have the top surfaces disposed at an almost same depth relative to said upper diffusion layer.

16. The semiconductor device according to claim 1, further comprising:
a protection resistance that is provided between said vertical MOS transistor and an external terminal and that decreases the surge voltage to said vertical MOS transistor; wherein
said vertical MOS transistor is an element to be protected that is protected by said first diode and said protection resistance.

17. The semiconductor device according to claim 1, further comprising:
a protection resistance that is provided between said vertical MOS transistor and an external terminal and that decreases the surge voltage to said vertical MOS transistor; wherein
the semiconductor device has a plurality of diodes that are at least any one of said first diodes and said second diodes;
among the plurality of the diodes, one diode is connected to a ground potential wiring or power potential wiring between an external terminal and said protection resistance, and other diode is connected to a ground potential wiring or power potential wiring between said protection resistance and said vertical MOS transistor; and
said vertical MOS transistor is an element to be protected that is protected by the plurality of the diodes and said protection resistance.

18. A semiconductor device, comprising:
an upper diffusion layer disposed in a semiconductor substrate surface;
a first lower diffusion layer of a first conductivity type and a second lower diffusion layer of a second conductivity type that are disposed in a lower surface lower than said semiconductor substrate surface;
an insulating film that isolates said first lower diffusion layer from said second lower diffusion layer and that upwardly projects from said lower surface; and
a first well of the first conductivity type disposed in a lower position than said first lower diffusion layer, said second lower diffusion layer and said insulating film; wherein
a surge voltage is discharged across said second lower diffusion layer and said first well when the surge voltage is applied.

19. The semiconductor device according to claim 18, comprising:
a conductive sidewall formed on a side wall of said insulating film.

20. The semiconductor device according to claim 18, wherein
said first lower diffusion layer is electrically connected to a ground potential wiring;
said second lower diffusion layer is electrically connected to an external terminal; and
the surge voltage is discharged to said ground potential wiring through said second lower diffusion layer, said first well and said first lower diffusion layer.
